(19) United States
(12) Patent Application Publication
(10) Pub. No.: US 2008/0296581 A1
(43) Pub. Date: Dec. 4, 2008

(54) Pixel structure and method for forming the same

(75) Inventors: Chih-Wei Chao, Hsin-Chu (TW); Yi-Sheng Cheng, Hsin-Chu (TW); Kun-Chih Lin, Hsin-Chu (TW); Yi-Wei Chen, Hsin-Chu (TW)

Correspondence Address: BACON & THOMAS, PLLC, 625 SLATERS LANE, FOURTH FLOOR, ALEXANDRIA, VA, 22314-1176, US

(73) Assignee: AU OPTRONICS CORP., Hsin-Chu (TW)

(21) Appl. No.: 11/892,191

(22) Filed: Aug. 21, 2007

(30) Foreign Application Priority Data
May 30, 2007 (TW) 96119397

(51) Int. Cl. H01L 21/00; H01L 29/786

(52) U.S. Cl. 257/71; 438/30; 257/E33.001; 257/E29.273

(57) ABSTRACT

A pixel structure including at least one thin-film transistor, at least one storage capacitor, a patterned first metal layer, an interlayer dielectric layer, a passivation layer, and a patterned pixel electrode is provided. The storage capacitor is electrically connected to the thin-film transistor. The patterned first metal layer is covered by the interlayer dielectric layer. The thin-film transistor and the interlayer dielectric layer are covered by the passivation layer, wherein an opening is formed in the passivation layer and a part of the interlayer dielectric layer. The patterned pixel electrode is formed on a part of the passivation layer and a part of the interlayer dielectric layer and contacted with a part of the passivation layer and a part of the interlayer dielectric layer. The storage capacitor includes the patterned first metal layer, a remained part of the interlayer dielectric layer located under the opening, and the patterned pixel electrode.

This application claims the benefit of Taiwan Application No. 096119397, filed May 30, 2007, the contents of which are herein incorporated by reference in its entirety.

### BACKGROUND OF THE INVENTION

1. Field of the Invention

The present invention relates in general to a pixel structure of a display device, and more particularly, to a storage capacitor structure of a pixel structure.

2. Description of the Related Art

A pixel structure has at least one transistor structure, wherein the gate receives scan signals from horizontal scan lines and the drain receives data signals from vertical data lines so as to provide the pixel with displaying signals. To prevent the display panel from losing its frame, the transistor has to maintain the level of the inputted charges unchanged when updating data. However, the liquid crystal capacitor is incapable of maintaining the charge level unchanged, therefore a storage capacitor is provided to maintain the charge level during the scanning period of the pixel.

Referring to FIG. 1, a cross-sectional view of the pixel structure of a conventional display panel is shown. Due to understanding a conventional method of resolving the above problem is stated below. The pixel structure 100 formed on a substrate 102 includes an indium tin oxide (ITO) layer 150, a passivation layer 140, an interlayer dielectric layer (ILD layer) 130, a gate insulating layer 120, a poly-crystal silicon layer 110 and a transistor 160. The gate 126 of the transistor 160 receives signals from the scan lines. The drain 124 of the transistor 160 is extended to the interlayer dielectric layer 130 to form a second metal layer 122b. A source 128 of the transistor 160 receives data signals from the data lines. The gate insulating layer 120 is disposed between a first metal layer 122a and the poly-crystal silicon layer 110. The passivation layer 140 is disposed on the source 128 and the drain 124. The indium tin oxide (ITO) layer 150 is a pixel electrode disposed on the passivation layer 140 and electrically connected to the drain 124 through an opening 152. The storage capacitor of the pixel structure 100 is formed by a storage capacitor Cp1 and a storage capacitor Cp2, wherein the storage capacitor Cp1 is formed by the first metal layer 122a, the gate insulating layer 120, and the poly-crystal silicon layer 110, and the storage capacitor Cp2 is formed by the second metal layer 122b, the interlayer dielectric layer 130, and the first metal layer 122a.

As the resolution standard expected of a display device is expected more, the pixel size is further reduced lest the aperture ratio of the pixel might be affected. If the aperture ratio is reduced, the design of capacitors will be compressed and the amount of capacitors will become inadequate. Moreover, if the storage capacitor is disposed between the metal layer 122a and the poly-crystal silicon layer 110, the poly-crystal silicon layer 110 can be unable to dope due to the restrictions in manufacturing process, hence resulting in an inadequate amount of storage capacitors.

### SUMMARY OF THE INVENTION

The present invention is directed to a pixel structure and a method for forming the same. By changing the structure of the storage capacitor of a pixel and the method for forming the same, the capacitance of the storage capacitor of the pixel is increased.

According to a first aspect of the present invention, a pixel structure including a substrate, a patterned semiconductor layer, a dielectric layer, a patterned first metal layer, an interlayer dielectric layer, a patterned second metal layer, a passivation layer, and a patterned pixel electrode is provided. The substrate has at least one transistor area and at least one capacitor area. The patterned semiconductor layer is formed on the substrate, wherein a part of the patterned semiconductor layer is located on the transistor area, and a part of the patterned semiconductor layer has a source region and a drain region. The patterned semiconductor layer and the substrate are covered by the dielectric layer. The patterned first metal layer formed on the dielectric layer is located on the transistor area and the capacitor area. The patterned first metal layer and the dielectric layer are covered by the interlayer dielectric layer having two first openings. The patterned second metal layer formed on a part of the interlayer dielectric layer is connected to the source region and the drain region through the first openings. The patterned second metal layer and the interlayer dielectric layer are covered by the passivation layer, wherein the passivation layer and a part of the interlayer dielectric layer have at least one second opening therein. The patterned pixel electrode formed on a part of the passivation layer and a part of the interlayer dielectric layer in the second opening is connected to one of the source region and the drain region through the patterned second metal layer.

According to a second aspect of the present invention, a pixel structure including at least one thin-film transistor, at least one storage capacitor, a patterned first metal layer, an interlayer dielectric layer, a passivation layer, and a patterned pixel electrode is provided. The storage capacitor is electrically connected to the thin-film transistor. The patterned first metal layer is covered by the interlayer dielectric layer. The thin-film transistor and the interlayer dielectric layer are covered by the passivation layer, wherein the passivation layer and a part of the interlayer dielectric layer have at least one opening therein. The patterned pixel electrode is formed on and contacted with a part of the passivation layer and a part of the interlayer dielectric layer. The storage capacitor includes the patterned first metal layer, a remained part of the interlayer dielectric layer, and the patterned pixel electrode.

According to a third aspect of the present invention, a method for forming a pixel structure is provided. The method includes: providing a substrate having at least one transistor area and at least one capacitor area. A patterned semiconductor layer is formed on the substrate, wherein a part of the patterned semiconductor layer formed on the transistor area having a source region and a drain region. The patterned semiconductor layer and the substrate are covered by a dielectric layer. A patterned first metal layer is formed on the dielectric layer on the transistor area and the capacitor area. The patterned first metal layer and the dielectric layer are covered by an interlayer dielectric layer having at least two first openings. A patterned second metal layer formed on a part of the interlayer dielectric layer is connected to the source region and the drain region through the first openings. The patterned second metal layer and the interlayer dielectric layer are covered by a passivation layer, wherein the passivation layer and a part of the interlayer dielectric layer have at least one second opening therein. A patterned pixel electrode formed on a part of the passivation layer and a part of the interlayer dielectric layer in the second opening is connected to one of the source region and the drain region through the patterned second metal layer.

According to a fourth aspect of the present invention, a method for forming a pixel structure having at least one thin-film transistor and at least one storage capacitor connected to the thin-film transistor is provided. The method includes: forming a patterned first metal layer. The patterned first metal layer is covered by an interlayer dielectric layer. The thin-film transistor and the interlayer dielectric layer are covered by a passivation layer, wherein the passivation layer and a part of the interlayer dielectric layer have at least one opening therein. A patterned pixel electrode is formed on and contacted with a part of the passivation layer and a part of the interlayer dielectric layer; wherein the storage capacitor includes the patterned first metal layer, a remained part of the interlayer dielectric layer, and the patterned pixel electrode.

The present invention will become apparent from the following detailed description of the preferred but non-limiting embodiments. The following description is made with reference to the accompanying drawings.

### BRIEF DESCRIPTION OF THE DRAWINGS

FIG. 1 (related art) is a cross-sectional view of the pixel structure of a conventional display panel;

FIG. 2 is a diagram of an electro-optical device according to an embodiment of the present invention;

FIG. 3A is a top view of a pixel structure of FIG. 2;

FIG. 3B is another structure top view of the pixel structure of FIG. 2;

FIG. 4A˜FIG. 4E are cross-sectional view of the forming method according to a first embodiment of the present invention;

FIG. 4F is a cross-sectional view along the cross-sectional line 4F-4F′ of FIG. 3A of the present invention;

FIG. 5A˜FIG. 5E are cross-sectional view of the forming method according to a second embodiment of the present invention;

FIG. 5F is another cross-sectional view along the cross-sectional line 4F-4F′ of FIG. 3A;

FIG. 6A is a top view of a dual-gate of the pixel structure of FIG. 2; and

FIG. 6B is a cross-sectional view along the cross-sectional line 6B-6B′ of FIG. 6A.

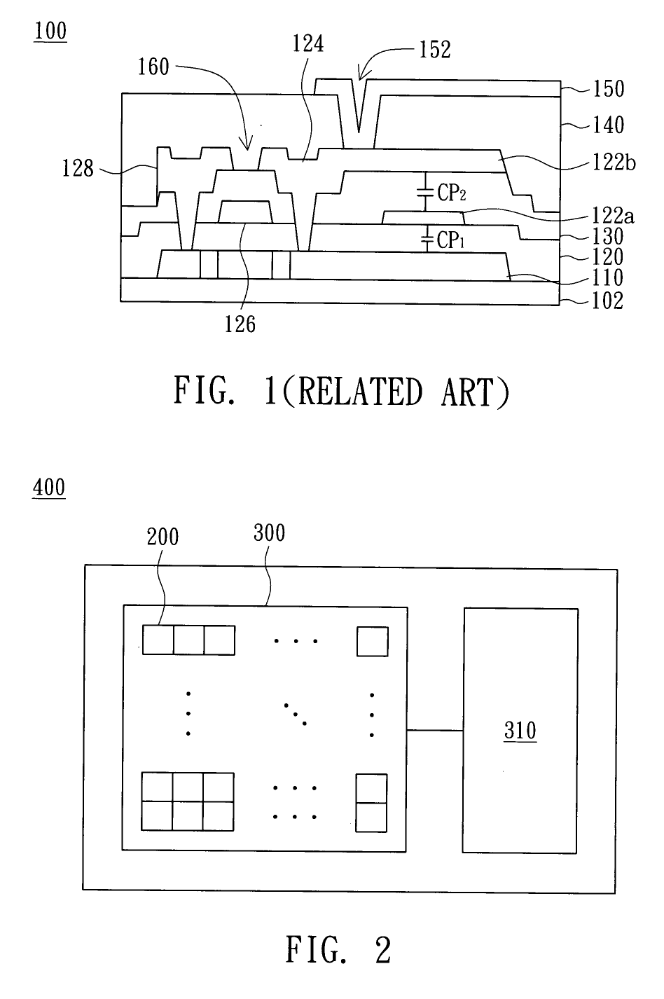

### DETAILED DESCRIPTION OF THE INVENTION

According to the pixel structure and the method for forming the same disclosed in the present invention, a storage capacitor is formed by a pixel electrode, a remained part of the interlayer dielectric layer, and a metal layer, hence increasing the capacitance without affecting the aperture ratio.

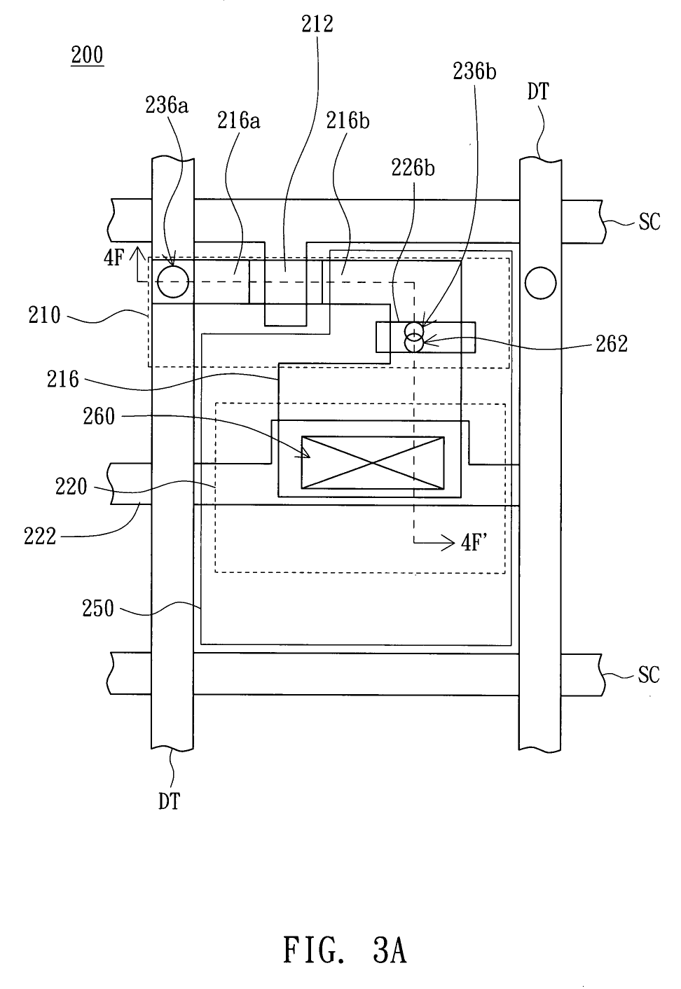

Referring to FIG. 2, a perspective diagram of an electro-optical device according to an embodiment of the present invention is shown. The electro-optical device 400 includes a display panel 300 and an electronic element 310 connected to the display panel 300. Examples of the electronic element 310 include controlling element, operating element, processing element, inputting element, memory element, driving element, illuminating element, protecting element, sensing element, detecting element, or elements of other functions, or a combination thereof. Examples of the electro-optical device 400 include portable electronic products (such as mobile phone, camera, notebook computer, game station, watch, music player, electronic photo frame, e-mail device, global positioning device, or others products, or combinations thereof, video-sonic device (such as video-sound player, or similars), monitor, television, indoor/outdoor watch board, panel of the projector, and so on. Besides, the variety of the display panel 300 is determined according to the material of the layer electrically contacted by at least one of the pixel electrode and the drain such as liquid crystal materials, organic electroluminescent material (such as micro-molecule, macromolecule, or a combination thereof), or a combination thereof. Examples of the display panel 300 is a liquid crystal display panel (such as transmissive panel, semi-transmissive panel, reflective panel, dual-display panel, vertical alignment (VA) panel, in-plane switching (IPS) panel, multi-domain vertical alignment (MVA) panel, twisted nematic (TN) panel, super twisted nematic (STN) panel, patterned vertical alignment (PVA) panel, super patterned vertical alignment (S-PVA) panel, advanced super view (ASV) panel, fringe-field switching (FFS) panel, continuous pinwheel alignment (CPA) panel, ax symmetric micelle(ASM) panel, optical compensation bend (OCB) panel, super in-plane switching (S-IPS) panel, advanced super in-plane switching (AS-IPS) panel, ultra fringe-field switching panel (UFFS), polymer stabilization alignment (PSA), dual-view panel, triple-view panel, or color filter on array (COA) panel, or array on color filter (AOC) panel, or other panels, or a combination thereof.), organic electroluminescent display panel, and semi-self-illuminant liquid crystal display. The display panel 300 is formed by a number of pixel structures 200 arranged in an array. In the embodiments disclosed below, different internal structures of the pixel structure 200 of the display panel 300 are elaborated by different embodiments. The first embodiment and the second embodiment are directed to a single gate of pixel structure 200, and the third embodiment is directed to a dual-gate of pixel structure 200.

### FIRST EMBODIMENT

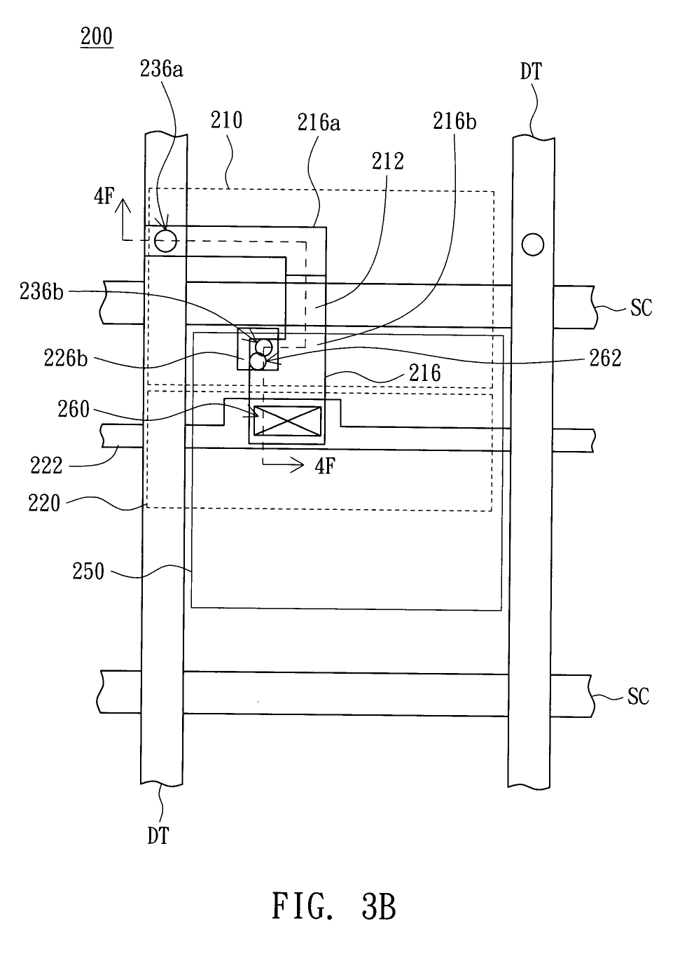

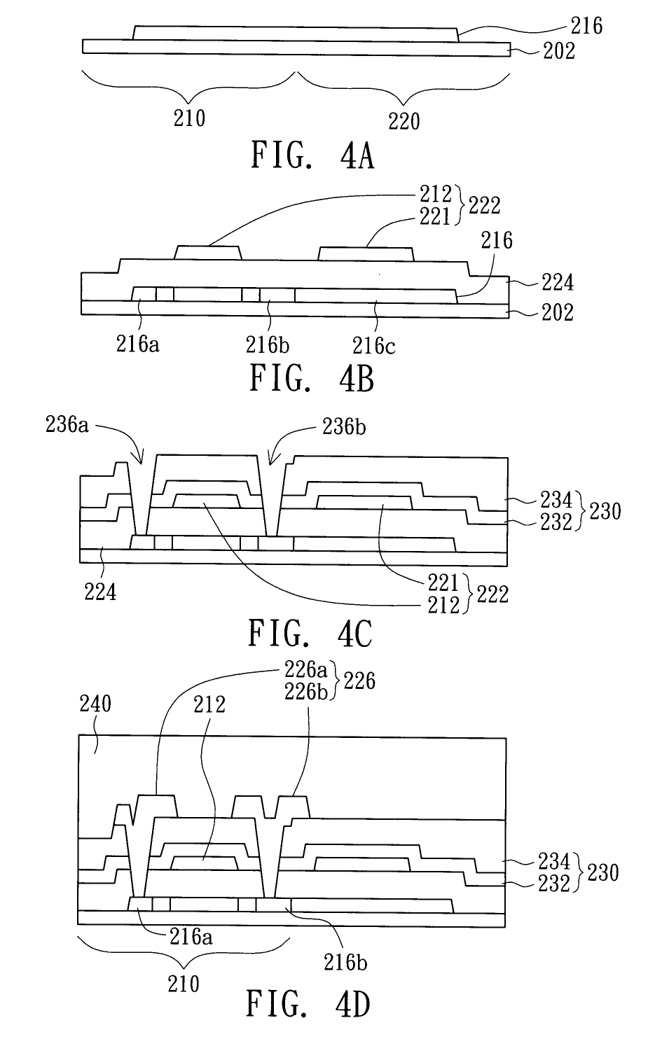

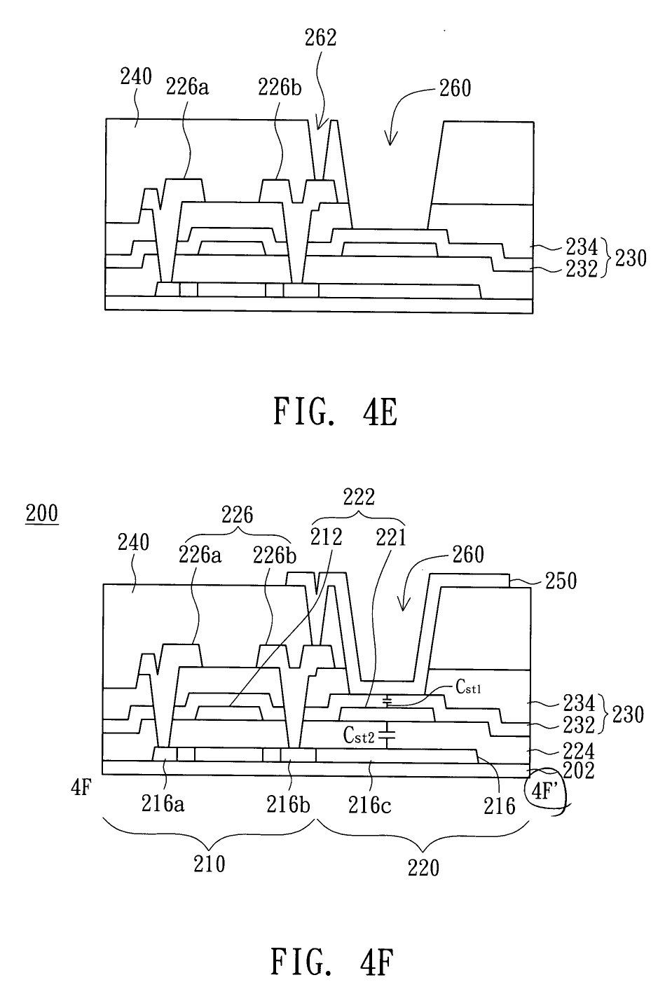

Referring to FIG. 3A, a top view of a pixel structure of FIG. 2 is shown. In FIG. 3A, the pixel structure 200 is disposed on the substrate 202 (not illustrated in FIGS. 3A and 3B), and the area defined by the scan lines SC and the data lines DT substantially interlaced with each other which has at least one switch element area 210 and at least one capacitor area 220. Material of the substrate 202 comprises a transparent material (such as glass, quartz, or other materials), a non-transparent material (such as silicon chip, ceramics, or other materials), a flexible material (such as thinner glass, polyester, polyalkane, poly-amide, polyol, poly-cycloalkane, poly aromatic series, or other materials, or a combination thereof), or a combination thereof. In the present embodiment of the invention, the substrate 202 is a transparent material made from glass for example, but is not limited thereto. In the present embodiment of the invention, the capacitor area 220 has a capacitor stacked structure (not illustrated), and the switch element area 210 has a thin-film transistor used as a switch control of the pixel structure 200 and electrically connected to the stacked capacitors located on the capacitor area 220. The gate 212 of the thin-film transistor is connected to the scan line SC, the patterned second metal layer 226 (not illustrated in 3A and 3B) is connected to a source region 216a of the patterned semiconductor layer 216 through one first opening 236a, wherein the patterned second metal layer 226 is used as a source electrode 226a (not illustrated in FIGS. 3A and 3B) electrically connected to the data line DT. Another part of the patterned second metal layer 226 is connected to a drain region 216b of the semiconductor layer 216 located on the capacitor area 220 through another first opening 236b, so that the patterned second metal layer 226 is used as a drain electrode 226b. Besides, the pixel electrode 250 is electrically connected to the drain electrode 226b through another opening 262. In other words, the source electrode 226a and drain electrode 226b have a gap located therebetween so that the source electrode 226a is apart from the drain electrode 226b. Moreover, the capacitor stacked structure located on the capacitor area 220 is used as a storage capacitor. The stacked capacitors are formed by a part of the semiconductor layer 216, a part of the patterned first metal layer 222, a part of the patterned pixel electrode 250, a dielectric layer 224, and an interlayer dielectric layer 230 (not illustrated in FIGS. 3A, 3B), wherein the dielectric layer 224 and the interlayer dielectric layer 230 are disposed between the part of the semiconductor layer 216 and the patterned pixel electrode 250. Referring to both FIG. 3A and FIG. 3B. FIG. 3B is another structure top view of the pixel structure of FIG. 2. FIG. 3A and FIG. 3B are two top views for pixel structures of different arrangement, and the cross-sectional views along the cross-sectional line 4F-4F′ are the same as illustrated in FIG. 4F.

Referring to both FIG. 3A and FIG. 4F, FIG. 4F is a cross-sectional view along the cross-sectional line 4F-4F′ of FIG. 3A of the present invention. The pixel structure 200 includes a substrate 202, a patterned semiconductor layer 216, a dielectric layer 224, a patterned first metal layer 222, an interlayer dielectric layer 230, a patterned second metal layer 226, a passivation layer 240, and a patterned pixel electrode 250, wherein the substrate 202 has at least one switch element area 210 and at least one capacitor area 220. The patterned semiconductor layer 216 is formed on the substrate 202. The substrate 202 and the patterned semiconductor layer 216 are covered by the dielectric layer 224. The patterned first metal layer 222 is formed on a part of the dielectric layer 224. The patterned first metal layer 222 and a part of the dielectric layer 224 are covered by the interlayer dielectric layer 230. The patterned second metal layer 226 is formed on a part of the interlayer dielectric layer 230. The interlayer dielectric layer 230 and the patterned second metal layer 226 are covered by the passivation layer 240, wherein a second opening 260 is formed deep into the passivation layer 240 and a part of the interlayer dielectric layer 230. The patterned pixel electrode 250 formed on and contacted with a part of the passivation layer 240 and a part of the interlayer dielectric layer 230 is electrically connected to the drain electrode 226b. The capacitor stacked structure located on the capacitor area 220 is used as a storage capacitor. The capacitor stacked structure includes a first capacitor Cst1 and a second capacitor Cst2, wherein the first capacitor Cst1 includes a patterned first metal layer 222 (such as the electrode 221), a remained part of the interlayer dielectric layer 230, and a patterned pixel electrode 250, the second capacitor Cst2 includes a patterned first metal layer 222 (such as the electrode 221), a dielectric layer 224, and a patterned semiconductor layer 216.

The method for forming the present embodiment of the invention is elaborated in FIGS. 4A˜4E.

Refer to both FIG. 4A and FIG. 4F. As indicated in FIG. 4A, a substrate 202 having at least one switch element area 210 and at least one capacitor area 220 is provided. Next, a patterned semiconductor layer 216 is formed on the substrate 202, wherein the patterned semiconductor layer 216 is located on the switch element area 210 and the capacitor area 220. Material of the patterned semiconductor layer 216 comprises an amorphous silicon-containing material, a poly-crystal silicon-containing material, a micro-crystal silicon-containing material, a single-crystal silicon-containing material, a germanium-containing material, or other materials, or a combination thereof. In the present embodiment of the invention, the patterned semiconductor layer 216 is exemplified to make from a poly-crystal silicon-containing material, but is not limited thereto.

Refer to both FIG. 4F and FIG. 4B. As indicated in FIG. 4B, the patterned semiconductor layer 216 and the substrate 202 are covered by a dielectric layer 224. Material of the dielectric layer 224 comprises an inorganic material (such as silicon oxide (SiOx), silicon nitride (SiNx), silicon nitrogen oxide (SiNxOx), silicon carbide (SiCx), fluorinated silicate glass, hafnium nitride (HfNx), or other materials, or a combination thereof), an organic material (such as photoresist, polyarylene ether (PAE), polyamide, polyester, polyol, polyalkane, benzocyclobutene (BCB), hydrogen silsesquioxane (HSQ), methyl silesquioxane (MSQ), silicon carbon oxide (SiOC-H), or other materials, or a combination thereof), or other materials, or a combination thereof. Next, a patterned first metal layer 222 is formed on the dielectric layer 224 to form a gate 212, a scan line SC (as indicated in FIG. 3A), and an electrode 221 of a storage capacitor located on the capacitor area 220. In the present embodiment of the invention, a doping process (not illustrated) is applied for the part of the patterned semiconductor layer 216 to form at least one source region 216a, at least one drain region 216b, and at least one another region (such as intrinsic region, but not illustrated) disposed between the source region 216a and the drain region 216b, and applied for another part of the patterned semiconductor layer 216 not doped located on the capacitor area 220 to form an intrinsic region 216 as an example, but not limited thereto. The doping process can be selectively applied after the formation of at least one of the patterned semiconductor layer 216, the dielectric layer 224, and the patterned first metal layer 222. Moreover, a doped semiconductor layer can be applied to the intrinsic region 216c of the patterned semiconductor layer 216 located on the capacitor area 220. Preferably, another doping region (not illustrated) is formed between the intrinsic region and at least one of the source region 216a and the drain region 216b and/or formed on the patterned semiconductor layer 216 located on the capacitor area 220. The doping concentration in the another doping region is substantially smaller than that in the source region 216a and the drain region 216b, hence the another doping region is also called a light doping region. In the present embodiment of the invention, the source region 216a and the drain region 216b of the patterned semiconductor layer 216, the intrinsic region of the switch element area 210, the intrinsic region 216c located on the capacitor area 220, and another doping region can be formed at or not at the same time.

Refer to both FIG. 4F and FIG. 4C. As indicated in FIG. 4C, the patterned first metal layer 222 and the dielectric layer 224 are covered by the interlayer dielectric layer 230. Next, a part of the interlayer dielectric layer 230 and the dielectric layer 224 are etched to form at least two first openings 236a and 236b is adapted to expose a part of the source region 216a and a part of the drain region 216b, respectively. In the present embodiment of the invention, the interlayer dielectric layer 230 preferred at least has a first sub-layer 232 and a second sub-layer 234, wherein the first sub-layer 232 and the second sub-layer 234 comprise an inorganic material (such as silicon oxide (SiOx), silicon nitride (SiNx), silicon nitrogen oxide (SiNxOx), silicon carbide (SiCx), fluorinated silicate glass, hafnium nitride (HfNx), or other materials, or a combination thereof, an organic material (such as photoresist, polyarylene ether (PAE), polyamide, polyester, polyol, polyalkane, benzocyclobutene (BCB), hydrogen silsesquioxane (HSQ), methyl silesquioxane (MSQ), silicon carbon oxide (SiOC-H), or other materials, or a combination thereof), or other materials, or a combination thereof. The two sub-layers can be made from substantially the same or substantially different materials. In the present embodiment of the invention, the first sub-layer 232 is made from silicon nitride (SiNₓ) and the second sub-layer 234 is made from silicon oxide (SiOₓ) as a example, but not limited thereto, and moverover the materials of the above-mentioned the two sub-layers are exchangeable each other.

Refer to both FIG. 4F and FIG. 4D. As indicated in FIG. 4D, the patterned second metal layer 226 formed on the second sub-layer 234 of a part of the interlayer dielectric layer 230 is electrically connected to the source region 216a and the drain region 216b through the first openings 236a and 236b, respectively. In the present embodiment of the invention, the switch element area 210 forms a switch element such as a thin-film transistor, and the patterned second metal layer 226 connected to the source region 216a is called a source electrode 226a and the part of the patterned second metal layer 226 connected to the drain region 216b is called a drain electrode 226b, and the patterned first metal layer 222 connected to the scan line SC (not illustrated in FIG. 4D) is called a gate electrode 212, wherein the source electrode 226a, the drain electrode 226b and the gate electrode 212 form a basic structure of a thin-film transistor for a switch control of the pixel 200. Next, the source electrode 226a and the drain electrode 226b, and the second sub-layer 234 of the interlayer dielectric layer 230 are covered by a passivation layer 240, and material of the passivation layer 240 comprises an inorganic material (such as silicon oxide (SiOx), silicon nitride (SiNx), silicon nitrogen oxide (SiNxOx), silicon carbide (SiCx), fluorinated silicate glass, hafnium nitride (HfNx), or other materials, or a combination thereof), an organic material (such as such as photoresist, polyarylene ether (PAE), polyamide, polyester, polyp, polyalkane, benzocyclobutene (BCB), hydrogen silsesquioxane (HSQ), methyl silesquioxane (MSQ), silicon carbon oxide (SiOC-H), or other materials, or a combination thereof), or other materials, or a combination thereof.

Refer to FIG. 4F and FIG. 4E. As indicated in FIG. 4E, at least one second opening 260 is formed deep into the passivation layer 240 and a part of the interlayer dielectric layer 230 is adapted to expose a part of the interlayer dielectric layer 230, and another opening 262 is formed deep into the passivation layer 240 is adapted to expose a part of the drain electrode 226b. The second opening 260 formed deep into a part of the interlayer dielectric layer 230, and the thickness of the remained part of the interlayer dielectric layer 230 not etched preferably is substantially equal to or substantially less than the thickness of the first sub-layer 232. For example, the thickness of the first sub-layer 232 ranges from about 100 Å to about 1,500 Å. In other words, the second opening 260 exposes a part of the first sub-layer 232 of the interlayer dielectric layer 230. In the present embodiment, material of the first sub-layer 232 and material of the second sub-layer 234 comprise silicon oxide (SiOₓ) and silicon nitride (SiNₓ), respectively as an example, and the etching method is determined according to the material of the interlayer dielectric layer 230. If the second sub-layer 234 is made from silicon oxide (SiOx), preferably a wet-etching method is used; if the second sub-layer 234 is made from silicon nitride (SiNₓ), preferably a dry-etching method is used. However, the application of etching method is not limited thereto. For example, the two etching methods are selectively exchangeable; the dry-etching method, the wet-etching method, or a combination thereof can be used to etch a particular layer no matter the second sub-layer 234 is made from silicon oxide, silicon nitride, or other materials.

Finally, referring to FIG. 4F, a patterned pixel electrode 250 formed on a part of the passivation layer 240 and a part of the interlayer dielectric layer 230 in the second opening 260 is electrically connected to the drain electrode 226b through another opening 262 (as indicated in FIG. 4E), wherein material of the patterned pixel electrode 250 comprises a transparent material (such as indium tin oxide, aluminum zinc oxide, cadmium tin oxide, indium zinc oxide, aluminum tin oxide, hafnium oxide, or other materials, or a combination thereof, a reflective material (such as aluminum (Al), gold (Au), silver (Ag), chromium (Cr), molybdenum (Mo), niobium (Nb), titanium, tantalum, hafnium, tungsten, neodymium, or an alloy thereof, or other materials, or a combination thereof), or a combination thereof. In the present embodiment of the invention, the patterned pixel electrode 250 is made from indium tin oxide (ITO) of the transparent material, but is not limited thereto.

The interlayer dielectric layer 230 is due to disposed between the patterned pixel electrode 250 and the patterned first metal layer 222 (such as the electrode 221), so that the capacitor stacked structure of the capacitor area 220 includes the first capacitor Cst1 formed by the patterned pixel electrode 250, the interlayer dielectric layer 230, and the patterned first mental layer 222 (such as the electrode 221), for example the interlayer dielectric layer 230 is the first sub-layer 232. Similarly, the dielectric layer 224 is due to disposed, between the patterned first metal layer 222 and the intrinsic region 216c of the patterned semiconductor layer 216. The capacitor stacked structure of the capacitor area 220 further includes the second capacitor Cst2 formed by the patterned first metal layer 222 (such as the electrode 221), dielectric layer 224, and the intrinsic region 216c of the patterned semiconductor layer 216. The first capacitor Cst1 and the second capacitor Cst2 are the storage capacitor of the pixel structure 200. Therefore, when data signals of the data line DT are transmitted to the source electrode 226a, the pixel voltage relevant to the data signals is stored in the first capacitor Cst1 and the second capacitor Cst2. Moreover, in the first capacitor Cst1, the interlayer dielectric layer 230 is etched to form the second opening 260 and reduce the thickness of the interlayer dielectric layer 230, hence increasing the capacitance of the capacitor. It is noted that in the present embodiment of the invention, the patterned semiconductor layer 216 can be formed on both the switch element area 210 and the capacitor area 220 of the substrate 202 at the same time or formed on the switch element area 210 only. If the patterned semiconductor layer 216 is formed on the switch element area 210 only, then the capacitor stacked structure only includes the first capacitor Cst1 formed by the patterned pixel electrode 250, the interlayer dielectric layer 230, and the patterned first metal layer 222 (such as the electrode 221).

### SECOND EMBODIMENT

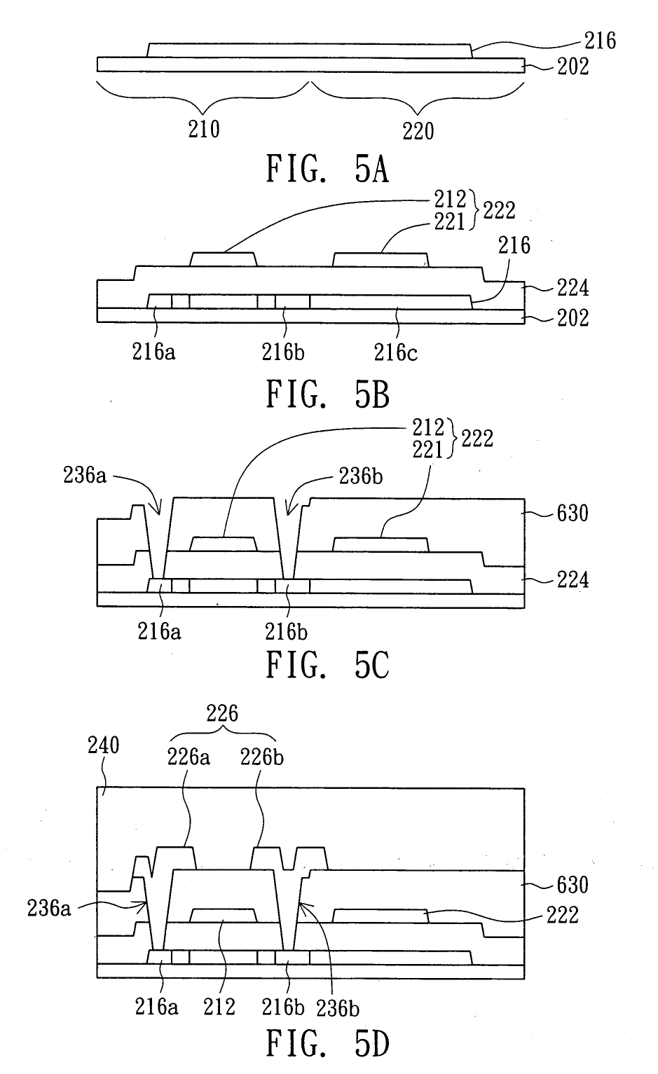

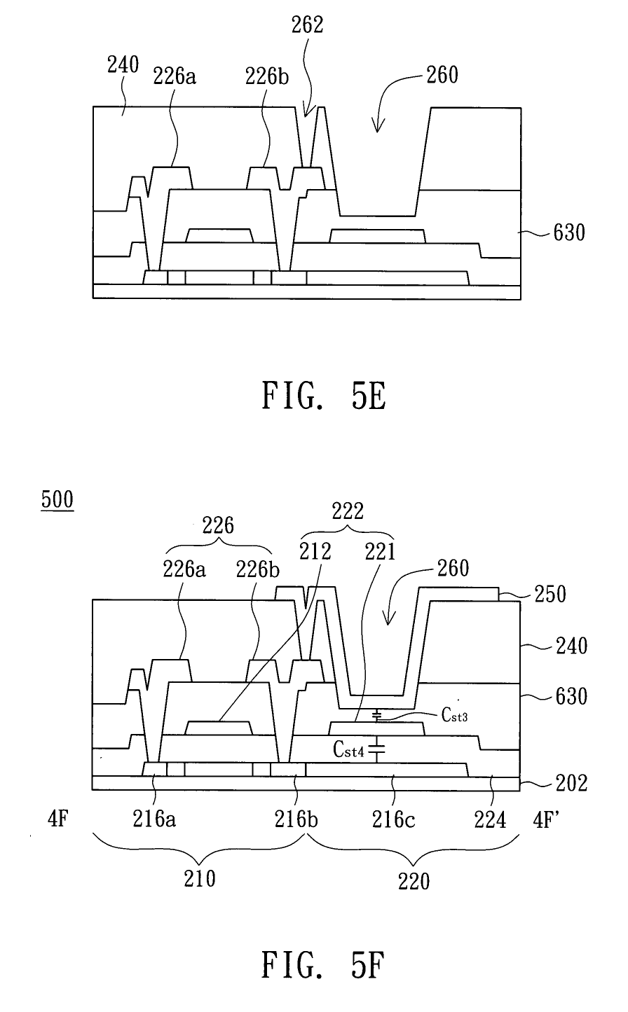

Refer to FIG. 4F and FIG. 5F. FIG. 5F is another cross-sectional view along the cross-sectional line 4F-4F′ of FIG. 3A. The second embodiment differs with the first embodiment in that the interlayer dielectric layer 230 used in the first embodiment is formed by two sub-layers but the interlayer dielectric layer 630 used in the second embodiment is single-layered. The top views of the pixel structure of the two embodiments are the same as that in FIGS. 3A and 3B, and are not repeated here. The method for forming the present embodiment of the invention is disclosed in FIGS. 5A˜5E.

Refer to both FIG. 5A and FIG. 5F. As indicated in FIG. 5A, a substrate 202 having a switch element area 210 and a capacitor area 220 is provided, wherein material of the substrate 202 comprises a transparent material (such as glass, quartz, or other materials), a non-transparent material (such as silicon chip, ceramics, or other materials), a flexible materials (such as polyester, polyalkane, polyamide, polyol, poly-cycloalkane, aromatic series, or other materials, or a combination thereof, or a combination thereof. In the present embodiment of the invention, the substrate 202 is made from a transparent material such as glass, but is not limited thereto. Next, a patterned semiconductor layer 216 is formed on the substrate 202, and the patterned semiconductor layer 216 is located on the switch element area 210 and the capacitor area 220. Material of the patterned semiconductor layer 216 comprises an amorphous silicon-containing material, a poly-crystal silicon-containing material, a micro-crystal silicon-containing material, a single-crystal silicon-containing material, a germanium-containing material, or other materials, or a combination thereof. In the present embodiment of the invention, the patterned semiconductor layer 216 is exemplified to make from a poly-crystal silicon-containing material, but is not limited thereto.

Refer to both FIG. 5B and FIG. 5F. As indicated in FIG. 5B, the patterned semiconductor layer 216 and the substrate 202 are covered by a dielectric layer 224. Material of the dielectric layer 224 comprises an inorganic material (such as silicon oxide (SiOx), silicon nitride (SiNx), silicon nitrogen oxide (SiNxOx), silicon carbide (SiCx), fluorinated silicate glass, hafnium nitride (HfNx), or other materials, or a combination thereof, organic material (such as photoresist, polyarylene ether (PAE), polyamide, polyester, polyp, polyalkane, benzocyclobutene (BCB), hydrogen silsesquioxane (HSQ), methyl silesquioxane (MSQ), silicon carbon oxide (SiOC-H), or other materials, or a combination thereof, or other materials, or a combination thereof. Next, a patterned first metal layer 222 is formed on the dielectric layer 224 to form a gate 212, a scan line SC (as indicated in FIG. 3A), and an electrode 221 of the storage capacitor located on the capacitor area 220. In the present embodiment of the invention, a doping process is applied for the part of the patterned semiconductor layer 216 to form at least one source region 216a, at least one drain region 216b and at least one another region (such as intrinsic region, but not illustrated) disposed between the source region 216a and the drain region 216b, and applied another part of the patterned semiconductor layer 216 not doped located on the capacitor area 220 to form an intrinsic region 216c. The doping process can be selectively applied after the formation of at least one of patterned semiconductor layer 216, the dielectric layer 224, and the patterned first metal layer 222. Moreover, a doped semiconductor layer can be applied to the intrinsic region 216c of the patterned semiconductor layer 216 located on the capacitor area 220. Preferably, at least one another doping region (not illustrated) is formed between the intrinsic region and at least one of the source region 216a and the drain region 216b and/or is formed on the patterned semiconductor layer 216 of the capacitor area 220. The doping concentration in the another doping region area being substantially smaller than that in the source region 216a and the drain region 216b is called a light doping region. In the present embodiment of the invention, the source region 216a, the drain region 216b, the intrinsic region on the switch element area 210, the intrinsic region 216c located on the capacitor area 220 and another doping region can be selectively formed at or not at the same time.

Refer to both FIG. 5C and FIG. 5F. As indicated in FIG. 5C, the patterned first metal layer 222 and the dielectric layer 224 are covered by an interlayer dielectric layer 630. Next, a part of the interlayer dielectric layer 630 and the dielectric layer 224 are etched to form at least two first openings 236a and 236b is adapted to expose a part of the source region 216a and a part of the drain region 216b. In the present embodiment of the invention, material of the interlayer dielectric layer 630 comprises an inorganic material (such as silicon oxide (SiOx), silicon nitride (SiNx), silicon nitrogen oxide (SiNxOx), silicon carbide (SiCx), fluorinated silicate glass, hafnium nitride (HfNx), or other materials, or a combination thereof, organic material (such as photoresist, polyarylene ether (PAE), polyamide, polyester, polyol, polyalkane, benzocyclobutene (BCB), hydrogen silsesquioxane (HSQ), methyl silsesquioxane (MSQ), silicon carbon oxide (SiOC-H), or other materials, or a combination thereof), or a combination thereof. In the present embodiment of the invention, the interlayer dielectric layer 630 is exemplified to make from silicon oxide (SiOₓ) or silicon nitride (SiNₓ).

Refer to both FIG. 5D and FIG. 5F. As indicated in FIG. 5D, a patterned second metal layer 226 formed on a part of the interlayer dielectric layer 630 is electrically connected to the source region 216a and the drain region 216b through the first openings 236a and 236b, respectively. In the present embodiment of the invention, the switch element area 210 forms a switch element such as a thin-film transistor, the patterned second metal layer 226 connected to the source region 216a is called a source electrode 226a, the patterned second metal layer 226 connected to the drain region 216b is called a drain electrode 226b, and the patterned first metal layer 222 connected to the scan line SC (referring to FIG. 3A) is called a gate electrode 212, wherein the source electrode 226a, the drain electrode 226b, and the gate electrode 212 form the basic structure of a thin-film transistor for a switch control of the pixel 200. Next, the patterned second metal layer 226 and the interlayer dielectric layer 630 are covered by a passivation layer 240, wherein the material of the passivation layer 240 comprises an inorganic material (such as silicon oxide (SiOx), silicon nitride (SiNx), silicon nitrogen oxide (SiNOx), silicon carbide (SiCx), fluorinated silicate glass, hafnium nitride (HfNx), or other materials, or a combination thereof), organic material (such as such as photoresist, polyarylene ether (PAE), polyamide, polyester, polyol, polyalkane, benzocyclobutene (BCB), hydrogen silsesquioxane (HSQ), methyl silesquioxane (MSQ), silicon carbon oxide (SiOC-H), or other materials, or a combination thereof, or other materials, or a combination thereof.

Refer to FIG. 5F and FIG. 5E. As indicated in FIG. 5E, at least one second opening 260 is formed deep into the passivation layer 240 and a part of the interlayer dielectric layer 630 is adapted to expose a part of the interlayer dielectric layer 630, and at least one another opening 262 is formed deep into the passivation layer 240 is adapted to expose a part of the drain electrode 226b. The second opening 260 formed deep into a part of the interlayer dielectric layer 630, and the thickness of the remained part of the interlayer dielectric layer 630 not etched preferably is substantially equal to or substantially less than 50% of the original thickness of the interlayer dielectric layer 630. For example, the thickness of the remained part of the interlayer dielectric layer 630 ranges from about 100 Å to about 1500 A. In the present embodiment of the invention, material of the interlayer dielectric layer 630 is made from silicon oxide (SiOₓ) or silicon nitride (SiNₓ) as an example, and the etching method is determined according to the material of the interlayer dielectric layer 630. If the interlayer dielectric layer 630 is made from silicon oxide (SiOx), preferably, a wet-etching method is used. If the interlayer dielectric layer 630 is made from silicon nitride (SiNₓ), preferably, a dry-etching method is used. However, the application of etching method is not limited thereto. For example, the two etching methods are selectively exchangeable, and the dry-etching method, the wet-etching method or a combination thereof can be used to etch a particular layer regardless of the material of the interlayer dielectric layer 630.

Finally, referring to FIG. 5F, a patterned pixel electrode 250 formed on a part of the passivation layer 240 and a part of the interlayer dielectric layer 230 in the second opening 260 is electrically connected to the drain electrode 226b through another opening 262 (as indicated in FIG. 5E), wherein material of the patterned pixel electrode 250 comprises a transparent material (such as indium tin oxide, aluminum zinc oxide, cadmium tin oxide, indium zinc oxide, aluminum tin oxide, hafnium oxide, or other materials, or a combination thereof, reflective material (such as aluminum (Al), gold (Au), silver (Ag), chromium (Cr), molybdenum (Mo), niobium (Nb), titanium, tantalum, hafnium, tungsten, neodymium, or an alloy thereof, or other materials, or a combination thereof, or a combination thereof. In the present embodiment of the invention, the patterned pixel electrode 250 is made from indium tin oxide (ITO) of the transparent material, but is not limited thereto.

The interlayer dielectric layer 630 is due to disposed between the patterned pixel electrode 250 and patterned first metal layer 222 (such as the electrode 221), so that the capacitor stacked structure of the capacitor area 220 includes a first capacitor Cst3 formed by the patterned pixel electrode 250, the interlayer dielectric layer 630 and the patterned first metal layer 222 (such as the electrode 221). Similarly, the dielectric layer 224 is disposed between the patterned first metal layer 222 so that the capacitor stacked structure of the capacitor area 220 further includes the second capacitor Cst4 formed by the patterned first mental layer 222 (such as the electrode), the dielectric layer 224 and the intrinsic region 216c of the patterned semiconductor layer 216. The first capacitor Cst3 and the second capacitor Cst4 are the storage capacitors of the pixel structure 200. Therefore, when data signals are transmitted to the source electrode 226a from the data lines DT, the pixel voltage relevant to the data signals is stored in the first capacitor Cst3 and the second capacitor Cst4. Moreover, in the first capacitor Cst3, the interlayer dielectric layer 630 is etched to form the second opening 260 and reduce the thickness of the interlayer dielectric layer 630, hence increasing the capacitance of the capacitor. It is noted that in the present embodiment of the invention, the patterned semiconductor layer 216 can be formed on both the switch element area 210 and the capacitor area 220 of the substrate 202 at the same time or on the switch element area 210 only. If the patterned semiconductor layer 216 is formed on the switch element area 210 only, then the capacitor stacked structure only includes the first capacitor Cst3 formed by the patterned pixel electrode 250, the interlayer dielectric layer 630 and the patterned first metal layer 222 (such as the electrode 221).

### THIRD EMBODIMENT

The third embodiment differs with the above two embodiments in that the storage capacitor used in the above two embodiments is a single gate of pixel structure but is a dual-gate of pixel structure in the present embodiment of the invention. The storage capacitor is exemplified by an interlayer dielectric layer, but is not limited thereto. The storage capacitor can also be exemplified by a multi-layered interlayer dielectric layer 230. The forming method, relevant materials and design conditions disclosed in above-mentioned embodiments are not repeated here.

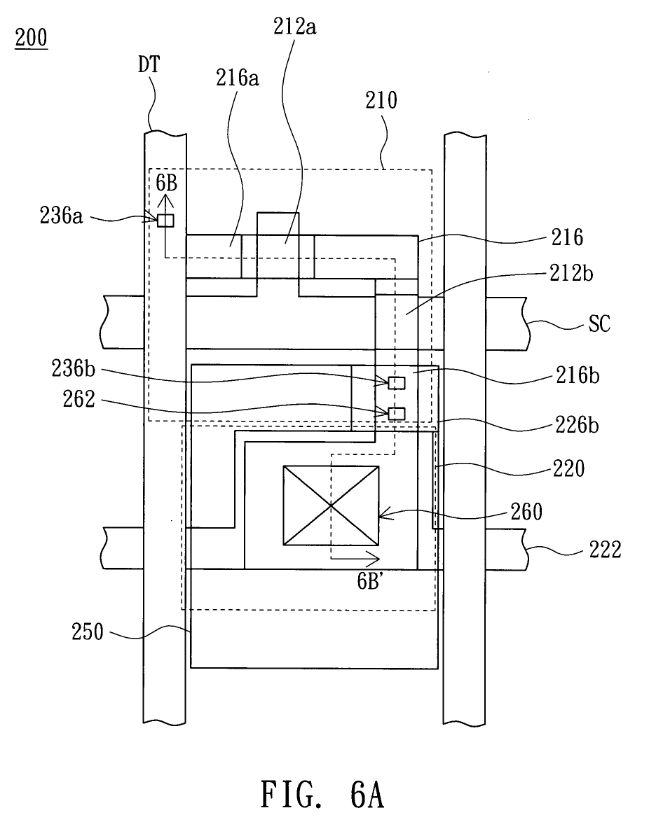

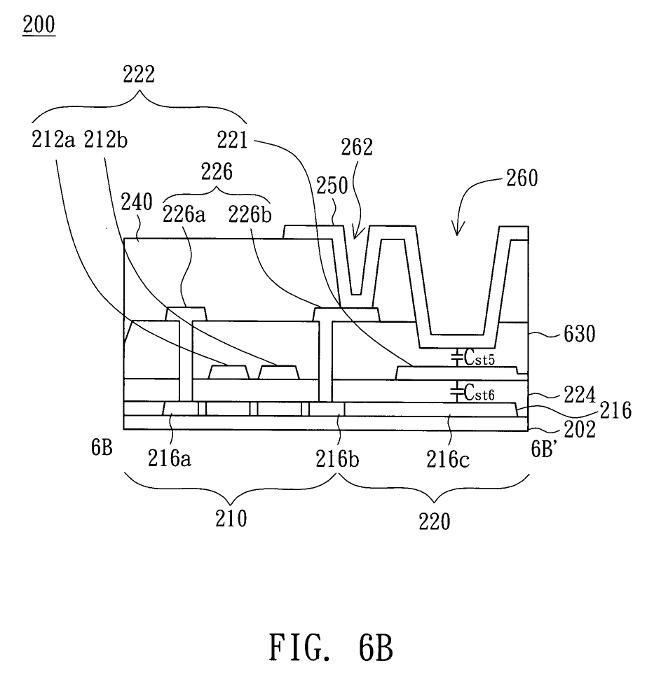

Refer to both FIG. 6A and FIG. 6B. FIG. 6A is a top view of a dual-gate pixel structure of FIG. 2. FIG. 6B is a cross-sectional view along the cross-sectional line 6B-6B′ of FIG. 6A. The pixel structure 200 disposed in the area defined by the scan lines SC and data lines DT substantially interlaced with each other which has at least one switch element area 210 and at least one capacitor area 220 on the substrate 202 (not illustrated in FIG. 6A) for example. In the present embodiment of the invention, the switch element area 210 has a thin-film transistor adapted to control the switch on/off of the pixel structure 200, and the capacitor area 220 has a capacitor stacked structure (not designated) used as a storage capacitor of the pixel structure 200. The thin-film transistor has at least two gates 212a and 212b connected to the scan lines SC. A part of a patterned second metal layer 226 (not illustrated in FIG. 6A) connected to the source region 216a of the patterned semiconductor layer 216 through the first opening 236a is used as a source electrode 226a, and the source electrode 226a is electrically connected to data line DT. The another part of the patterned second metal layer 226 connected to the drain region 216b of the semiconductor layer 216 through another first opening 236b is used as a drain electrode 226b. Besides, the patterned pixel electrode 250 is electrically connected to the drain electrode 226b through at least one another opening 262. Moreover, the capacitor stacked structure of the capacitor area 220 used as a storage capacitor is formed by the intrinsic region 216c of a part of the patterned semiconductor layer 216 (as indicated in FIG. 6B), the patterned first metal layer 222 (such as electrode 221), a part of the pixel electrode 250, a dielectric layer 224, and an interlayer dielectric layer 630 (as indicated in FIG. 6B) wherein the dielectric layer 224 and the interlayer dielectric layer 630 are disposed between the pixel electrode 250 and the part of the semiconductor layer 215.

Referring to FIG. 6B, a cross-sectional view along the cross-sectional line 6B-6B′ of FIG. 6A is shown. The pixel structure 200 includes a substrate 202 having at least one switch element area 210 and at least one capacitor area 220, a patterned semiconductor layer 216, a dielectric layer 224, a patterned first metal layer 222, an interlayer dielectric layer 630, a patterned second metal layer 226, a passivation layer 240, and a patterned pixel electrode 250. The patterned semiconductor layer 216 is formed on the substrate 202. The substrate 202 and the patterned semiconductor layer 216 are covered by the dielectric layer 224. The patterned first metal layer 222 is formed on a part of the dielectric layer 224 to form the gate electrodes 212a and 212b, the scan line SC, and the electrode 221 of the storage capacitor located on the capacitor area 220. The patterned first metal layer 222 and a part of the dielectric layer 224 are covered by the interlayer dielectric layer 630. The patterned second metal layer 226 is formed on a part of the interlayer dielectric layer 630. The patterned second metal layer 226 and the interlayer dielectric layer 630 are covered by the passivation layer 240, and the second opening 260 is disposed deep into the passivation layer 240 and a part of the interlayer dielectric layer 630. The patterned pixel electrode 250 is formed on and contacted with a part of the passivation layer 240 and a part of the interlayer dielectric layer 630, and the patterned pixel electrode 250 is electrically connected to the drain 226b through another opening 262. Material of the patterned pixel electrode 250 comprises a transparent material (such as indium tin oxide, aluminum zinc oxide, cadmium tin oxide, indium zinc oxide, aluminum tin oxide, or other materials, or a combination thereof, reflective material (such as aluminum (Al), gold (Au), silver (Ag), chromium (Cr), molybdenum (Mo), niobium (Nb), titanium, tantalum, tungsten, neodymium, or an alloy thereof, or other materials, or a combination thereof, or a combination thereof. In the present embodiment of the invention, the patterned pixel electrode 250 is made from an indium tin oxide (ITO) of the transparent material, but is not limited thereto as an example.

In the present embodiment of the invention, the switch element area 210 forms a switch element such as a thin-film transistor, so that the patterned second metal layer 226 connected to the source region 216a is called a source electrode 226a and the patterned second metal layer 226 connected to the drain region 216b is called a drain electrode 226b, and the patterned first metal layer 222 connected to the scan line SC is called gate electrodes 212a and 212b. The source electrode 226a, the drain electrode 226b, and the gate electrodes 212a and 212b form the basic structure of a thin-film transistor for a switch control of the pixel 200.

The interlayer dielectric layer 630 is disposed between the patterned pixel electrode 250 and patterned first metal layer 222 (such as the electrode 221), so that the capacitor stacked structure of the capacitor area 220 includes a first capacitor Cst5 formed by the patterned pixel electrode 250, the interlayer dielectric layer 630 and the patterned first metal layer 222 (such as the electrode 221). Similarly, the dielectric layer 224 is disposed between the patterned first metal layer 222 and the intrinsic region 216c of the patterned semiconductor layer 216, so that the capacitor stacked structure of the capacitor area 220 further includes a second capacitor Cst6 formed by the patterned first metal layer 222 (such as the electrode 221), the dielectric layer 224 and the intrinsic region 216c of the patterned semiconductor layer 216. The first capacitor Cst5 and the second capacitor Cst6 are the storage capacitors of the pixel structure 200. Therefore, when data signals are transmitted to the source electrode 226a from the data line DT (as indicated in FIG. 6A), the pixel voltage relevant to the data signals is stored in the first capacitor Cst5 and the second capacitor Cst6. Moreover, in the first capacitor Cst5, the interlayer dielectric layer 630 is etched to form the second opening 260 and reduce the thickness of the interlayer dielectric layer 630, hence increasing the capacitance of the capacitor. It is noted that in the present embodiment of the invention, the patterned semiconductor layer 216 can be formed on both the switch element area 210 and the capacitor area 220 of the substrate 202 at the same time or on the switch element area 210 only. If the patterned semiconductor layer 216 is formed on the switch element area 210 only, then the capacitor stacked structure only includes the first capacitor Cst5 formed by the patterned pixel electrode 250, the interlayer dielectric layer 630, and the patterned first metal layer 222 (such as the electrode 221). Despite the present embodiment of the invention is exemplified by a single-layered interlayer dielectric layer 630, the interlayer dielectric layer 230 at least having a first sub-layer 232 and a second sub-layer 234 as disclosed in the above-mentioned embodiments may do as well. The remained part of the dielectric layer 230 located under the opening 260 has the same design as disclosed in above-mentioned embodiments. The present embodiment of the invention may use the similar material and the similar etching methods used in the above-mentioned embodiments of the invention.

According to the cross-sectional view of the pixel structure disclosed in the above-mentioned embodiments of the invention, brief description is stated below. A substrate 202 having at least one switch element area 210 and at least one capacitor area 220. The switch element area 210 has at least one thin-film transistor (not illustrated), and the capacitor area 220 has the stacked structure of a storage capacitor, wherein the storage capacitor is electrically connected to the thin-film transistor. Then, a patterned first metal layer 222 is provided and the patterned first metal layer 222 is covered by an interlayer dielectric layer 630. The thin-film transistor (not illustrated) and the interlayer dielectric layer 630 are covered by a passivation layer 240, wherein at least one opening 260 is disposed in the passivation layer 240 and a part of the interlayer dielectric layer 630. A patterned pixel electrode 250 is formed on and contacted with a part of the passivation layer 240 and a part of the interlayer dielectric layer 630, wherein the storage capacitor (such as Cst1, Cst3, Cst5 and so on) includes the patterned first metal layer 222 (such as electrode 221), a remained part of the interlayer dielectric layer 630 located under the opening 260, and the patterned pixel electrode 250. Furthermore, if the capacitor area 220 has an additional patterned semiconductor layer 216, the additional patterned semiconductor layer 216 can form a second capacitor (such as Cst2, Cst4, Cst6) with at least one layer (such as the dielectric layer 224) between the additional patterned semiconductor layer 216 and the patterned first metal layer 222 (such as electrode 221). In the above-mentioned embodiments of the invention, the thin-film transistor formed by the patterned semiconductor layer 216, the dielectric layer 224, and the patterned first metal layer 222 in a sequential order is a typical top-gate thin-film transistor, but is not limited thereto. However, the formation order of the patterned semiconductor layer 216, the dielectric layer 224, and the patterned first metal layer 222 can be changed. For example, if the sequential order of formation is the patterned first metal layer 222 comes first, the dielectric layer 224 comes second and the patterned semiconductor layer 216 comes last, then the thin-film transistor formed accordingly is a typical bottom-gate thin-film transistor. Therefore, the thin-film transistor on the switch element area 210 of the above-mentioned embodiments of the invention can selectively be a top-gate thin-film transistor, a bottom-gate thin-film transistor, or a thin-film transistor of other types as long as the structure of the storage capacitor on the capacitor area 220 complies with the design disclosed in the above-mentioned embodiment of the present invention. Moreover, in the above-mentioned embodiments of the present invention, the opening 262 through which the patterned pixel electrode 250 is connected to the drain electrode 226b does not substantially correspond to the opening 236b through which the patterned semiconductor layer 216 is connected to the drain 226b, but is not limited thereto. However, the two openings can selectively correspond to each other exactly or substantially. Moreover, in the above-mentioned embodiments of the present invention, the two first openings 236a and 236b are formed by etching the interlayer dielectric layer 630 and the dielectric layer 224 or by etching the interlayer dielectric layer 230 and the dielectric layer 224, but are not limited thereto. The dielectric layer 224 can be etched to form at least two openings first, then at least another two openings are formed in the interlayer dielectric layer 630 or 230 by etching after the interlayer dielectric layer 630 or 230 is formed. The another two openings substantially correspond to the two openings in the dielectric layer 224.

According to the pixel structure and method for forming the same disclosed in the above-mentioned embodiments of the present invention, the capacitance of the storage capacitor of the pixel structure is increased by the thickness of the interlayer dielectric layer is reduced. Then, a capacitor forms by the pixel electrode; the patterned first metal layer, and a remained part of the interlayer dielectric layer. By reducing the thickness of the capacitor formed by the interlayer dielectric layer, the capacitance of the storage capacitor of the pixel structure is increased efficiently without affecting the aperture ratio of the pixel structure. Moreover, the capacitance decreasing problem of storage capacitor which arises if the patterned semiconductor layer can not be doped due to the restriction in the manufacturing process is resolved as well.

While the present invention has been described by way of example and in terms of three preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A pixel structure, comprising:
a substrate having at least one transistor area and at least one capacitor area;
a patterned semiconductor layer formed on the substrate, wherein a part of the patterned semiconductor layer is disposed on the transistor area, and the part of the patterned semiconductor layer has at least one source region and at least one drain region;
a dielectric layer covering the patterned semiconductor layer and the substrate;
a patterned first metal layer formed on the dielectric layer of the transistor area and the dielectric layer of the capacitor area;
an interlayer dielectric layer covering the patterned first metal layer and the dielectric layer;
a patterned second metal layer, formed on a part of the interlayer dielectric layer, and electrically connected to the source region and the drain region;
a passivation layer, covering the patterned second metal layer and the interlayer dielectric layer, wherein the passivation layer and the interlayer dielectric layer has at least one opening therein, so as to expose a remained part of the interlayer dielectric layer; and
a patterned pixel electrode, formed on a part of the passivation layer and the remained part of the interlayer dielectric layer of the opening, and electrically connected to the patterned second metal layer.

2. The pixel structure according to claim 1, wherein the capacitor area has a first capacitor formed by the patterned pixel electrode, the remained part of the interlayer dielectric layer under the opening, and the patterned first metal layer located on the capacitor area.

3. The pixel structure according to claim 1, wherein another part of the patterned semiconductor layer is formed on the capacitor area.

4. The pixel structure according to claim 3, wherein the capacitor area has a second capacitor formed by the patterned first metal layer located on the capacitor area, the dielectric layer, and the another part of the patterned semiconductor layer located on the capacitor area.

5. The pixel structure according to claim 1, wherein the thickness of the remained part of interlayer dielectric layer is substantially equal to or substantially less than 50% of the original thickness of the interlayer dielectric layer.

6. The pixel structure according to claim 1, wherein the thickness of the remained part of interlayer dielectric layer ranges from about 100 angstrom (Å) to about 1,500 angstrom (Å).

7. The pixel structure according to claim 1, wherein the interlayer dielectric layer has a first sub-layer and a second sub-layer.

8. The pixel structure according to claim 7, wherein at least one of the material of the first sub-layer and the material of the second sub-layer comprises an inorganic material, an organic material, or combinations thereof.

9. The pixel structure according to claim 7, wherein the thickness of the remained part of interlayer dielectric layer is substantially equal to or substantially less than the thickness of the first sub-layer.

10. The pixel structure according to claim 9, wherein the thickness of the first sub-layer ranges from about 100 angstrom (Å) to about 1,500 angstrom (Å).

11. The pixel structure according to claim 7, wherein the capacitor area has a first capacitor formed by the patterned pixel electrode, the first sub-layer, and the patterned first metal layer located on the capacitor area.

12. The pixel structure according to claim 11, wherein another part of the patterned semiconductor layer is formed on the capacitor area.

13. The pixel structure according to claim 12, wherein the capacitor area has a second capacitor formed by the patterned first metal layer located on the capacitor area, the dielectric layer, and the another part of the patterned semiconductor layer located on the capacitor area.

14. The pixel structure according to claim 1, wherein the material of the passivation layer comprises an inorganic material, an organic material, or combinations thereof.

15. A pixel structure, comprising:
at least one thin-film transistor;
a patterned first metal layer;
an interlayer dielectric layer covering the patterned first metal layer;
a passivation layer covering the thin-film transistor and the interlayer dielectric layer, wherein the passivation layer and a part of the interlayer dielectric layer has at least one opening therein, so as to expose a remained part of the interlayer dielectric layer; and
a patterned pixel electrode formed on and contacted with a part of the passivation layer and the remained part of the interlayer dielectric layer, wherein a first storage capacitor formed by the patterned first metal layer, the remained part of the interlayer dielectric layer under the opening, and the patterned pixel electrode, and the first storage capacitor is electrically connected to the thin-film transistor.

16. The pixel structure according to claim 15, further comprising a patterned semiconductor layer formed under the patterned first metal layer, so that the patterned semiconductor layer and the patterned first metal layer has a dielectric layer is disposed therebetween.

17. The pixel structure according to claim 16, wherein a second storage capacitor is formed by the patterned semiconductor layer, the dielectric layer, and the patterned first metal layer.

18. The pixel structure according to claim 15, wherein the thickness of the remained part of the interlayer dielectric layer is substantially equal to or substantially less than 50% of the original thickness of the interlayer dielectric layer

19. The pixel structure according to claim 15, wherein the thickness of the remained part of the interlayer dielectric layer ranges from about 100 angstrom (Å) to about 1,500 angstrom (Å).

20. The pixel structure according to claim 15, wherein the interlayer dielectric layer has a first sub-layer and a second sub-layer.

21. The pixel structure according to claim 20, wherein at least one of the material of the first sub-layer and the material of the second sub-layer comprises an inorganic material, an organic material, or combinations thereof.

22. The pixel structure according to claim 20, wherein the thickness of the remained part of the interlayer dielectric layer is substantially equal to or substantially less than the thickness of the first sub-layer.

23. The pixel structure according to claim 22, wherein the thickness of the first sub-layer ranges from about 100 angstrom (Å) to about 1,500 angstrom (Å).

24. The pixel structure according to claim 20, wherein the remained part of the interlayer dielectric layer under the opening is the first sub-layer.

25. The pixel structure according to claim 20, further comprising a patterned semiconductor layer formed under the patterned first metal layer, so that the patterned semiconductor layer and the patterned first metal layer have a dielectric layer which is disposed therebetween.

26. The pixel structure according to claim 25, wherein a second storage capacitor is formed by the patterned semiconductor layer, the dielectric layer, and the patterned first metal layer.

27. The structure according to claim 15, wherein the material of the passivation layer comprises an inorganic material, an organic material, or combinations thereof.

28. A display panel incorporating the pixel structure of claim 1.

29. A display panel incorporating the pixel structure of claim 15.

30. An electro-optical device incorporating the pixel structure of claim 28.

31. An electro-optical device incorporating the pixel structure of claim 29.

32. A method for forming a pixel structure, the method comprising:
providing a substrate having a transistor area and a capacitor area;
forming a patterned semiconductor layer on the substrate, wherein a part of the patterned semiconductor layer is formed on the transistor area has at least one source region and at least one drain region;
forming a dielectric layer on the patterned semiconductor layer and the substrate;
forming a patterned first metal layer on the dielectric layer of the transistor area and the dielectric layer of the capacitor area;
forming an interlayer dielectric layer having at least two first openings on the patterned first metal layer and the dielectric layer;
forming a patterned second metal layer on a part of the interlayer dielectric layer, wherein the patterned second metal layer is connected to the source region and the drain region through the first openings;
forming a passivation layer on the patterned second metal layer and the interlayer dielectric layer, wherein passivation layer and the interlayer dielectric layer have at least one second opening therein, so as to expose a remained part of the interlayer dielectric layer; and
forming a patterned pixel electrode on a part of the passivation layer and the remained part of the interlayer dielectric layer of the second opening, and electrically connecting to the patterned second metal layer.

33. The method according to claim 32, wherein a first capacitor is formed by the patterned pixel electrode located on the capacitor area, the remained part of the interlayer dielectric layer under the second opening, and the patterned first metal layer located on the capacitor area.

34. The method according to claim 32, wherein another part of the patterned semiconductor layer is formed on the capacitor area.

35. The method according to claim 34, wherein a second capacitor is formed by the patterned first metal layer located on the capacitor area, the dielectric layer, and the another part of patterned semiconductor layer.

36. The method according to claim 32, wherein the thickness of the remained part of the interlayer dielectric layer is substantially equal to or substantially less than 50% of the original thickness of the interlayer dielectric layer.

37. The method according to claim 32, wherein the thickness of the remained part of the interlayer dielectric layer ranges from about 100 angstrom (Å) to about 1,500 angstrom (Å).

38. The method according to claim 32, wherein the interlayer dielectric layer has a first sub-layer and a second sub-layer.

39. The method according to claim 38, wherein the thickness of the remained part of the interlayer dielectric layer under the second opening is substantially equal to or substantially less than the thickness of the first sub-layer.

40. The method according to claim 39, wherein the thickness of the first sub-layer ranges from about 100 angstrom (Å) to about 1,500 angstrom (Å).

41. The method according to claim 38, wherein a capacitor is formed by the patterned pixel electrode located on the capacitor area, the first sub-layer, and the patterned first metal layer.

42. The method according to claim 38, wherein another part of the patterned semiconductor layer formed on the capacitor area.

43. The method according to claim 38, wherein a capacitor is formed by the patterned first metal layer located on the capacitor area, the dielectric layer, and the another part of the patterned semiconductor layer.

44. A method for forming a pixel structure having at least one thin-film transistor, the method comprising:
forming a patterned first metal layer;
forming an interlayer dielectric layer on the patterned first metal layer;
forming a passivation layer on the thin-film transistor and the interlayer dielectric layer, wherein the passivation layer and the interlayer dielectric layer have at least one opening therein, so as to expose a remained part of the interlayer dielectric layer; and
forming a patterned pixel electrode, and contacting with a part of the passivation layer and the remained part of the interlayer dielectric layer;
wherein, a first storage capacitor is formed by the patterned first metal layer, a remained part of the interlayer dielectric layer under the opening, and the patterned pixel electrode.

45. The method according to claim 44, further comprising forming a patterned semiconductor layer under the patterned first metal layer, so that the patterned semiconductor layer and the patterned first metal layer have a dielectric layer which is disposed therebetween.

46. The method according to claim 45, wherein a second storage capacitor is formed by the patterned semiconductor layer, the dielectric layer, and the patterned first metal layer.

47. The method according to claim 44, wherein the thickness of the remained part of the interlayer dielectric layer is substantially equal to or substantially less than 50% of the original thickness of the interlayer dielectric layer.

48. The method according to claim 44, wherein the thickness of the remained part of the interlayer dielectric layer ranges from about 100 angstrom (Å) to about 1,500 angstrom (A).

49. The method according to claim 44, wherein the interlayer dielectric layer has a first sub-layer and a second sub-layer.

50. The method according to claim 49, wherein the thickness of the remained part of the interlayer dielectric layer is substantially equal to or substantially less than the thickness of the first sub-layer.

51. The method according to claim 50, wherein the thickness of the first sub-layer ranges from about 100 angstrom (Å) to about 1,500 angstrom (A).

52. The method according to claim 49, wherein the first storage capacitor is formed by the patterned pixel electrode, the first sub-layer, and the patterned first metal layer.

53. The method according to claim 52, further comprising forming a patterned semiconductor layer under the patterned first metal layer, so that the patterned semiconductor layer and the patterned first metal layer have a dielectric layer which is disposed therebetween.

54. The method according to claim 53, wherein a second storage capacitor is formed by the patterned semiconductor layer, the dielectric layer, and the patterned first metal layer.

55. The method for forming a display panel incorporating the method for forming a pixel structure of claim 32.

56. The method for forming a display panel incorporating the method for forming a pixel structure of claim 44.

57. The method for forming an electronic device incorporating the method for forming a display panel of claim 55.

58. The method for forming an electronic device incorporating the method for forming a display panel of claim 56.
